(19) United States
(12) Patent Application Publication
(10) Pub. No.: US 2025/0006591 A1
(43) Pub. Date: Jan. 2, 2025

(54) STANDARD-CELL CIRCUITS TO MITIGATE SCALING-RELATED PARASITICS

(71) Applicant: Intel Corporation, Santa Clara, CA (US)

(72) Inventors: Nischal Arkali Radhakrishna, Hillsboro, OR (US); Chinhsuan Chen, Portland, OR (US); Sivakumar Venkataraman, Hillsboro, OR (US); Somashekar Bangalore Prakash, Portland, OR (US); Marni Nabors, Portland, OR (US)

(73) Assignee: Intel Corporation, Santa Clara, CA (US)

(21) Appl. No.: 18/217,022

(22) Filed: Jun. 30, 2023

(51) Int. Cl. H01L 23/48; H01L 23/522; H01L 23/528; H10B 41/10; H10B 41/27; H10B 41/35; H10B 43/10; H10B 43/27; H10B 43/35

(52) U.S. Cl. CPC H01L 23/481; H01L 23/5226; H01L 23/5283; H10B 41/10; H10B 41/27; H10B 41/35; H10B 43/10; H10B 43/27; H10B 43/35

(57) ABSTRACT

An integrated circuit (IC) device may include standard cells with multiple parallel paths interconnecting transistors at a device level and over a transistor, in a higher layer of an interconnect structure. The parallel paths may include multiple power supply via contacts on a transistor source structure and multiple supply interconnect lines over the transistor and coupling the transistor to an associated power supply. The parallel paths may include multiple output via contacts on an integrated transistor drain structure and multiple output interconnect lines over a complementary transistor device. The parallel paths may include separate, rather than shared or integrated, adjacent source structures coupled to a same power supply.

### BACKGROUND

To continually increase transistor counts at each technology node (e.g., as described by Moore's Law), standard cells in integrated circuit (IC) devices are continually packed into less and less area. Smaller cell dimensions increase interconnect resistances. Parasitic capacitances may also increase as transistor elements and other structures are brought closer together.

As interconnect widths (and other dimensions) decrease, circuits and structures may be co-optimized to maintain and improve interconnect (and other) performance. Improved structures and methods are needed to optimize IC operation, e.g., at higher frequencies, as standard cells are miniaturized.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A, 1B, 1C, and 1D illustrate plan views of an inverter device, including transistor structures between supply lines and isolated views of various levels, in accordance with some embodiments;

FIGS. 2A, 2B, and 2C illustrate plan and schematic views of portions of an inverter device, including supply interconnects and vias over a source structure of a transistor structure, in accordance with some embodiments;

FIGS. 3A, 3B, and 3C illustrate plan, cross-sectional profile, and schematic views of portions of an inverter device, including parallel output interconnects coupling an output line to drain structures, in accordance with some embodiments;

FIGS. 4A, 4B, and 4C illustrate plan views of a NAND device, including transistor structures between supply lines and an isolation trench between transistor structures, in accordance with some embodiments;

FIGS. 5A and 5B illustrate plan and schematic views of a NAND device, including adjacent source structures separated by an isolation trench, in accordance with some embodiments;

FIG. 6 illustrates a diagram of an example data server machine employing an integrated circuit (IC) device having standard cells with improved interconnection schemes, in accordance with some embodiments; and

FIG. 7 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected.” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Structures and techniques are disclosed to improve the performance of integrated circuit (IC) devices having standard cells with reduced dimensions, including conductors with reduced thicknesses and elements with reduced pitches to adjacent elements. As interconnect cross-sectional dimensions are decreased, e.g., in an effort to increase device density, interconnect resistances may increase and consequently reduce drive current to transistors. Additional power supply lines may be employed to reduce interconnect resistances between devices and larger power rails. Some added supply lines may be strategically deployed as shielding between signal lines. Output connections between or within complementary devices may be shunted, e.g., coupled at multiple levels, to reduce output resistances. Shared transistor connections may be split out to provide parallel current paths and mitigate resistance bottlenecks.

Critical paths in high-performance applications (such as client and server cores that rely heavily on single-threaded performance) are dominated by high-drive cells. Rather than universally using standard cells with a minimized number of interconnects, e.g., to deliver power from power rails to source structures, strategically using performance-optimized standard cells can result in significant frequency improvements for some of the high-usage cells. For example, interconnect resistances may be reduced, which reduces RC (resistive-capacitive) delays. These frequency gains may be achieved with minimal switching energy increase if interconnects are properly arranged, resulting in iso-power performance gains as well. These structural and circuit improvements may be implemented alongside or instead of new process features, which are not required to enhance standard-cell performance. For example, these structural and circuit improvements may be applied selectively to high drive cells in a design while leaving the small drive cells unmodified.

Additional power supply lines may be employed to reduce interconnect resistances between larger power rails and transistors. By double-strapping power interconnects, e.g., adding a parallel path at an intermediate interconnect layer between power rails and transistors, voltage drops in the distribution networks powering transistors may be minimized and transistor currents improved, resulting in higher performance of the standard-cell circuit.

Some of these added supply lines may be strategically deployed as shielding between signal lines. Power supplies and power rails delivering direct current (DC) power may be small-signal grounds, e.g., decoupled from alternating current (AC) or other voltage transients. Signal-grounded supply interconnects may beneficially provide superior shielding (relative to, e.g., floating nodes), and minimizing mutual coupling, between signal lines. Output and input lines carrying high-speed signals may be shielded from each other by routing between added DC supply lines. Benefits of this type of shielding are even more significant when the input and output signals are switching in the opposite direction, as in the case of inverters (and for other circuits at least much of the time).

Output resistances may be reduced by shunting output connections between or within complementary devices, for example, by coupling parallel output paths at multiple levels. Transistor outputs may be shunted at the devices, e.g., coupling outputs at drain contacts, as well as in an interconnect layer. Both parallel paths may be used by either of pull-up or pull-down transistors whenever the other transistor is off.

Shared transistor connections, such as at source or drain contacts, may be split out (e.g., isolated) to provide parallel current paths and mitigate resistance bottlenecks. For example, source resistances may be minimized in series-connected pull-down networks.

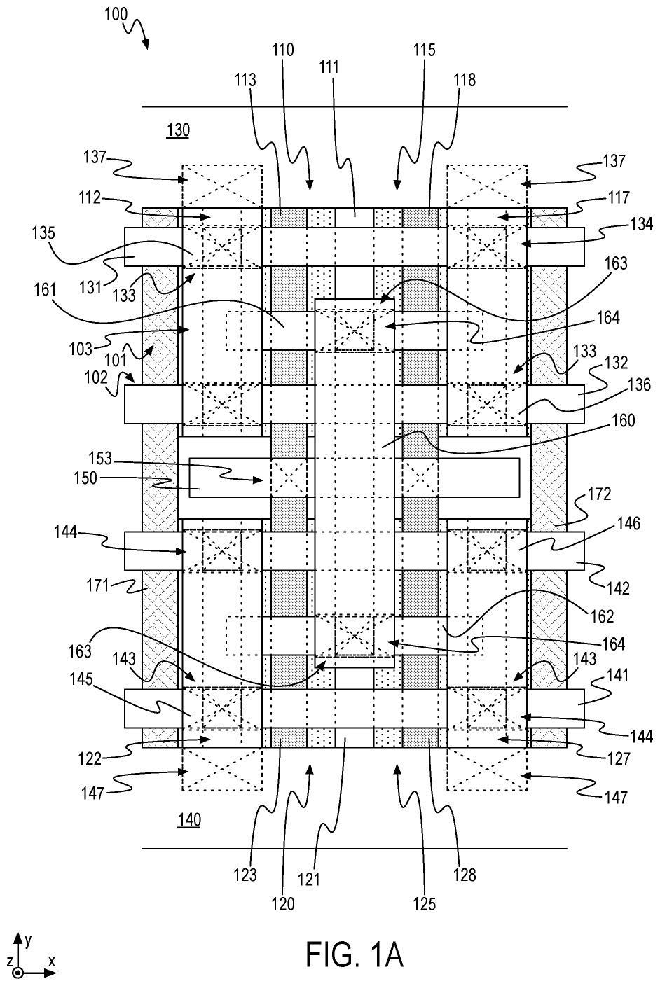

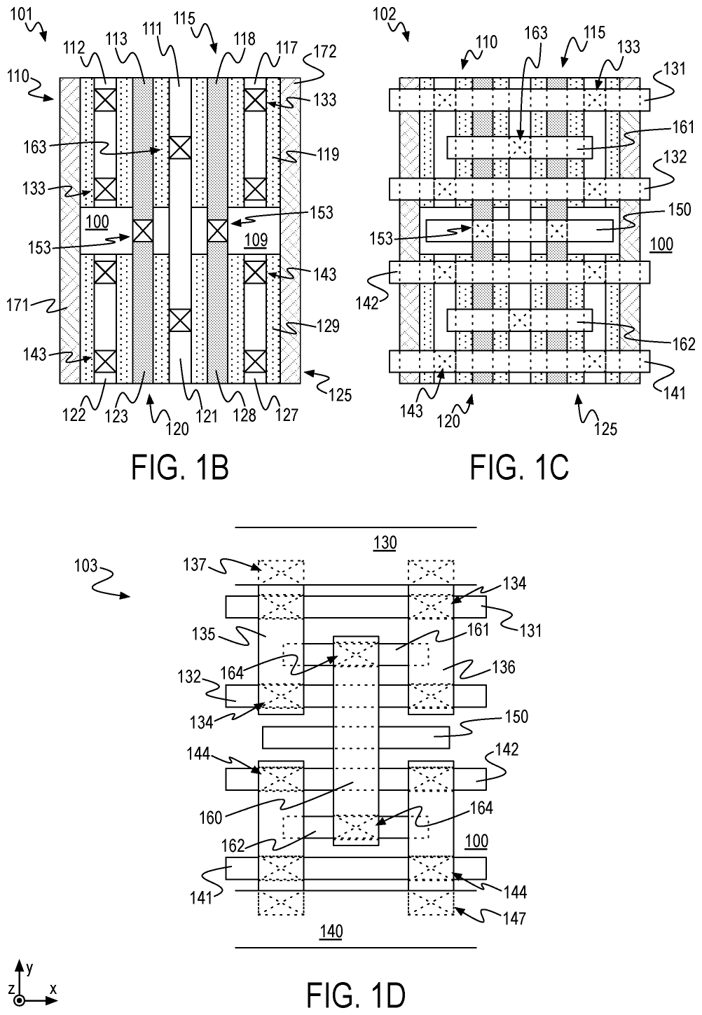

FIGS. 1A, 1B, 1C, and 1D illustrate plan views of inverter device 100, including transistor structures 110, 115, 120, 125 between supply lines 130, 140 and isolated views of various levels 101, 102, 103, in accordance with some embodiments. FIG. 1A illustrates device 100, including transistor structures 110, 115, 120, 125 and various interconnections at, under, and over levels 101, 102, 103. FIG. 1B shows first level 101 of device 100. Vias 133, 143, 153, 163 are over, or within, first level 101, and interconnect elements of level 101 to elements of a second level 102 (shown in FIG. 1C). Contact vias 133, 143, 153, 163 may be considered to be within or at level 101. FIG. 1C illustrates second level 102 of device 100, as well as elements of, or at, first level 101. Elements at first level 101 obscured by (e.g., under) elements at second level 102 are illustrated with dashed lines. FIG. 1D shows third level 103 of device 100, including power supply interconnect lines 135, 136, 145, 146 over and between supply interconnect lines 131, 132, 141, 142, as well as supply lines 130, 140 over level 103.

Device 100 may be deployed as a standard cell in an array of standard cells, for example, in a processor or other IC die. Device 100 includes transistor structures 110, 115, 120, 125 under supply lines 130, 140; input line 150; output line 160; and various interconnect structures between transistor structures 110, 115, 120, 125 and lines 130, 140, 150, 160. Elements of IC device 100 at levels 101, 102, 103 (and over level 103) are shown. At least some elements obscured by (e.g., under) other elements are illustrated with dashed lines. Vias within or between levels are represented as dashed rectangles with diagonals between opposite corners (e.g., a dashed rectangle with a dashed X). At least some vias may have other (e.g., non-rectangular) shapes.

Device 100 may be a standard cell deployed to perform a specific logic (or other) function in a defined area. For example, the embodiment of FIG. 1A is an inverter. An input signal to device 100 may be present at input line 150 (e.g., provided by an external circuit or device, such as another device 100), and device 100 may produce an output signal at output line 160 that has an opposite logic value. In some embodiments, a low voltage level (e.g., below a certain threshold) at input line 150 results in a high voltage level at output line 160. In some such embodiments, a high voltage level (e.g., above a certain threshold) at input line 150 results in a low voltage level at output line 160. For example, a high-voltage input signal may be a voltage level at, near, or otherwise approaching a voltage provided by supply line 130, and a low-voltage input signal may be a voltage level at, near, or otherwise approaching a voltage provided by supply line 140. Other input, output, and threshold levels may be utilized. Other embodiments may provide other (e.g., logic) functions.

At level 101 (e.g., FIG. 1B), transistor structure 110 includes drain structure 111, source structure 112, and gate structure 113. Transistor structure 115 includes source structure 117 and gate structure 118, as well as drain structure 111, which is shared by transistor structures 110, 115. Transistor structure 120 includes drain structure 121, source structure 122, and gate structure 123. Transistor structure 125 includes source structure 127 and gate structure 128, as well as drain structure 121, which is shared by transistor structures 120, 125. Drain structures 111, 121 are coupled at level 101, for example, by a contact metal or a continuous stripe of impurity doped semiconductor material.

Transistor structures 110, 115 may be of one type (e.g., n-channel or p-channel field-effect transistors (FETs), such as metal-oxide semiconductor (MOS) FETs), and transistor structures 120, 125 may be of another type. For example, in the embodiment of FIG. 1A, device 100 is complementary MOS (CMOS) device with p-type transistor structures 110, 115 and n-type transistor structures 120, 125. A low-voltage input (e.g., a logic level 0) at line 150 may cause p-type transistor structures 110, 115 to conduct and n-type transistor structures 120, 125 to not conduct, which may isolate output line 160 from low-voltage line 140 and electrically connect line 160 to high-voltage line 130, providing a high-voltage output (e.g., a logic level 1). A high-voltage input (e.g., a logic level 1) at line 150 may cause n-type transistor structures 120, 125 to conduct and p-type transistor structures 110, 115 to not conduct, which may isolate output line 160 from high-voltage line 130 and electrically connect line 160 to low-voltage line 140, providing a low-voltage output (e.g., a logic level 0).

Supply lines 130, 140 may be power rails providing electrical power to transistor structures 110, 115, 120, 125. Supply lines 130, 140 may couple transistor structures 110, 115, 120, 125 to separate power supplies (e.g., Vcc and Vss) and may provide power at different voltage levels. (Vcc, which sometimes refers to a “collector voltage,” does not necessarily imply that any of transistor structures 110, 115, 120, 125 are bipolar junction transistors (BJT) or limit a voltage level on supply lines 130, 140. Vss may refer to a “source voltage,” but does not necessarily limit transistor structures 110, 115, 120, 125 to a certain transistor type or limit a voltage level on supply lines 130, 140.) Voltage line 130 may couple transistor structures 110, 115 to a positive voltage and, voltage line 140 may couple transistor structures 120, 125 to ground (or a negative voltage).

Transistor structures 110, 115 are coupled at source structures 112, 117 to line 130 by electrically parallel supply interconnect lines 131, 132 at level 102 (e.g., FIG. 1C). Transistor structures 120, 125 and source structures 122, 127 are similarly coupled to line 140 by electrically parallel supply interconnect lines 141, 142 at level 102. Transistor structures 110, 115 are coupled to line 130 by electrically parallel supply interconnect lines 135, 136 at level 103 and over interconnect lines 131, 132 at level 102. Transistor structures 120, 125 are coupled to line 140 by electrically parallel supply interconnect lines 145, 146 at level 103 and over interconnect lines 141, 142 at level 102. Each supply interconnect line is an electrically conductive structure, such as a metallization line, extending laterally and coupling between a transistor structure and one of power supply lines 130, 140.

Supply lines 130, 140 are power rails over interconnect lines 135, 136, 145, 146 at level 103. Supply line 130 is coupled to interconnect lines 135, 136 by vias 137 at or over level 103. Supply line 140 is coupled to interconnect lines 145, 146 by vias 147 at or over level 103. Interconnect lines 135, 136 are coupled to interconnect lines 131, 132 by vias 134 at or over level 102. Interconnect lines 145, 146 are coupled to interconnect lines 141, 142 by vias 144 at or over level 102. Interconnect lines 131, 132 are coupled to source structures 112, 117 by contact vias 133 at or over level 101. Interconnect lines 141, 142 are coupled to source structures 122, 127 by contact vias 143 at or over level 101.

Input line 150 is at level 102 and is coupled to gate structures 113, 118, 123, 128 by input contact vias 153.

Output line 160 is at level 103 and is coupled to drain structures 111, 121. Output line 160 is over and coupled to output interconnect lines 161, 162, which are at level 102. Output contact vias 163 are at level 101 (or between levels 101, 102) and couple drain structures 111, 121 and output interconnect lines 161, 162. Output vias 164 are at level 102 (or between levels 102, 103) and couple output line 160 and output interconnect lines 161, 162. An output interconnect line may be a conductive structure, such as a metallization line, extending laterally and coupling between a transistor structure and output line 160.

Device 100 includes isolations 171, 172 (or portions of isolations 171, 172), which may be trench isolation structures separating and/or bordering similar devices 100 on both sides of the illustrated device 100.

FIG. 1B shows level 101 of device 100, including key portions of transistor structures 110, 115, 120, 125, unobscured by elements of device 100 at levels 102, 103. Transistor structures 110, 115, 120, 125 are in or on a substrate 109. Vias at level 101 (or between levels 101, 102) are represented as rectangles with both diagonals (e.g., an X spanning the rectangle). The vias shown couple elements of device 100 at level 101 with elements over level 101, e.g., level 102, which is illustrated at FIG. 1C.

Source and gate structures 112, 113 of transistor structure 110 and source and gate structures 117, 118 of transistor structure 115 are shown on either side of drain structure 111, which is shared by transistor structures 110, 115. Each of transistor structures 110, 115 and source structures 112, 117 are coupled to a power rail (e.g., supply line 130 over level 103, shown at FIG. 1D) by a pair of electrically parallel interconnect lines 131, 132 at level 102 (e.g., shown at FIG. 1C) and a pair of electrically parallel contact vias 133. Separate contact vias 133 couple source structure 112 to each of interconnect lines 131, 132. Other separate contact vias 133 couple source structure 117 to each of interconnect lines 131, 132.

Contact vias are substantially vertical, electrically conductive (e.g., metal) structures that contact a structure at level 101 and couple the contacted structure with an element above the contacted structure. For example, contact vias 133 couple source structures 112, 117 to interconnect lines 131, 132, and contact vias 143 couple source structures 122, 127 to interconnect lines 141, 142. Contact vias 153 couple gate structures 113, 118 to input line 150. Contact vias 163 couple drain structures 111, 121 to output interconnect lines 161, 162.

Transistor structures 110, 115 may be of the same conductivity type (e.g., n-channel or p-channel FETs) and are in or on a same well 119 or substrate. Transistor structures 120, 125 may be of the same type (e.g., n-channel or p-channel FETs) in or on a same well 129 or substrate. Transistor structures 110, 115 may be of a type complementary to transistor structures 120, 125. In the example, device 100 is a CMOS device with pull-up p-type transistor structures 110, 115 (e.g., in n-well 119) and complementary pull-down n-type transistor structures 120, 125 (e.g., in p-well 129).

Source and gate structures 122, 123 of transistor structure 120 and source and gate structures 127, 128 of transistor structure 125 are shown on either side of drain structure 121, which is shared by transistor structures 120, 125. Each of transistor structures 120, 125 and source structures 122, 127 are coupled to a power rail (e.g., supply line 140 over level 103, shown at FIG. 1D) by a pair of electrically parallel interconnect lines 141, 142 at level 102 (e.g., shown at FIG. 1C) and a pair of electrically parallel contact vias 143. Separate contact vias 143 couple source structure 122 to each of interconnect lines 141, 142. Other separate contact vias 143 couple source structure 127 to each of interconnect lines 141, 142.

Transistor structures 110, 115, 120, 125 include channel regions (not shown) under corresponding gate structures. The channel regions couple drain structures to corresponding source structures. Channel regions may be of any suitable form or material (e.g., a semiconductor doped or undoped). In some embodiments, transistor structures 110, 115, 120, 125 are nonplanar transistors. In some embodiments, transistor structures 110, 115, 120, 125 are FinFETs and include channel regions within fins of semiconductor material. In some embodiments, transistor structures 110, 115, 120, 125 include channel regions within nanoribbons (or nanosheets or nanowires) of semiconductor material. Channel regions within nanoribbons may be wide enough to be considered nanosheets (e.g., with wide channel regions) or narrow enough to be considered nanoribbons or nanowires (e.g., with narrow channel regions). In the embodiment of FIG. 1B, channel regions of device 100 and transistor structures 110, 115, 120, 125 extend in the x direction, under gate structures 113, 118, 123, 128. In some embodiments, each of transistor structures 110, 115, 120, 125 include channel regions within multiple fins, nanoribbons, etc. For example, transistor structure 110 may have a channel region that includes three parallel fins running in the x direction from source structure 112 to drain structure 111 and under gate structure 113.

Gate structures 113, 118, 123, 128 extend in the y direction. Gate structures 113, 118, 123, 128 include at least an insulator portion and a conductive electrode portion. The electrode portion may conduct a control signal (such as an input signal voltage) in the corresponding transistor structure, and the insulator portion may enable electrostatic control of a channel region by the gate electrode and gate voltage. The insulator portion may include one or more materials, e.g., multiple layers over each channel region. In some embodiments, a gate insulator includes silicon and oxygen (e.g., in a silicon oxide (e.g., silicon dioxide) and/or silicon oxynitride). In some embodiments, a gate dielectric includes a high-permittivity (or “high-K”) dielectric, for example, hafnium oxide. A dielectric material may include one or more oxides, such as metal oxides, alone or in combination. In some embodiments, a dielectric material includes an added dopant, e.g., to increase a permittivity of the dielectric material. A high-K dielectric material may include one or more of various elements, such as hafnium, silicon, oxygen, titanium, tantalum, lanthanum, aluminum, zirconium, barium, strontium, yttrium, lead, scandium, niobium, and zinc. Other materials may be suitable.

The gate electrode may be of any suitably conductive material. In many embodiments, gate electrodes of structures 113, 118, 123, 128 include silicon, e.g., a polysilicon. A highly doped polycrystalline silicon may provide certain advantages, such as ease of fabrication (e.g., with few defects and in combination with a silicon oxide dielectric, as well as feasibility with high-temperature operations) and modulation of transistor threshold voltage. In many embodiments, gate electrodes of structures 113, 118, 123, 128 include one or more metals, such as tantalum, tungsten, titanium, cobalt, nickel, etc. In some such embodiments, a gate electrode includes nitrogen, e.g., in a tantalum nitride or titanium nitride. Other materials may be suitable. In some embodiments, a gate electrode includes polysilicon alloyed with one or more metals.

Some of gate structures 113, 118, 123, 128 may be integrated in a combined, substantially continuous structure, e.g., at one interconnect level. For example, gate structures 113, 118 may include substantially continuous gate electrodes that couple transistor structures 110, 115 to input line 150 (shown in FIG. 1C) through via 153. Similarly, gate structures 123, 128 may include substantially continuous gate electrodes that couple transistor structures 120, 125 to input line 150 (shown in FIG. 1C) through a separate via 153. In the embodiment of FIG. 1B, contact vias 153 are over gate structures 113, 118, 123, 128, which may provide benefits (such as improved performance at higher frequencies).

Source structures 112, 117, 122, 127 extend in the y direction. Source structures 112, 117, 122, 127 may contact channel regions at an end opposite of drain structures 111, 121. Source structures 112, 117, 122, 127 may include any suitably conductive material. In the example, structures 112, 117, 122, 127 include one or more contact metals, such as tantalum, tungsten, titanium, platinum, cobalt, nickel, etc., with or without nitrogen. In some embodiments, source structures 112, 117, 122, 127 include a semiconductor material (e.g., heavily doped with an electrically active impurity) that couples to semiconductor material of a channel structure. Other materials may be suitable.

Notably, each of source structures 112, 117, 122, 127 are coupled to one of supply lines 130, 140 by two separate vias 133. Vias 133 may be located at or near ends of source structures 112, 117, 122, 127 (FIG. 1B). In some embodiments, transistor structures 110, 115, 120, 125 include channel regions within multiple, parallel structures (such as fins), and vias 133 are located at or near ends of some channel structures, while one or more channel structures contact one of source structures 112, 117, 122, 127 between vias 133.

With source structures 112, 117 coupled, for example, by supply interconnect line 131 (as shown in FIG. 1C) and sharing drain structure 111, transistor structures 110, 115 are in electrical parallel. Similarly, source structures 122, 127 share drain structure 121 and are coupled by supply interconnect line 132, and transistor structures 120, 125 are in parallel. These parallel transistors may be referred to as legs, which may add drive current to a standard cell (e.g., device 100) output while maintaining a cell height (e.g., in the y direction). Other parallel legs may be present in some devices 100.

Drain structures 111, 121 extend in the y direction. Drain structures 111, 121 may contact channel regions at an end opposite source structures 112, 117, 122, 127. Drain structures 111, 121 may be in contact and be over channel regions. Channel regions may be in continuous structures (e.g., fins or nanoribbons) that extend, for example, from source structures 112, 122 to source structures 117, 127. Drain structures 111, 121 may include any suitably conductive material. In the example, structures 111, 121 include one or more contact metals, such as tantalum, tungsten, titanium, platinum, cobalt, nickel, etc., with or without nitrogen. In some embodiments, drain structures 111, 121 include a semiconductor material (e.g., heavily doped with an electrically active impurity) that couples to semiconductor material of a channel structure. Other materials may be suitable.

Notably, drain structures 111, 121 are coupled to each other at level 101 and are both coupled to output line 160 by two vias 163. Drain structures 111, 121 may be integrated in a combined, substantially continuous structure, e.g., at an uppermost surface at level 101.

Device 100 is in or on substrate 109. Substrate 109 may be, for example, an integrated circuit (IC) die or wafer, and may be of any suitable material or materials. The substrate may include a semiconductor or insulator material, including a crystalline material. In some embodiments, the substrate includes monocrystalline silicon (Si), germanium (Ge), silicon germanium (SiGe), a III-V alloy material (e.g., gallium arsenide (GaAs)), a silicon carbide (e.g., SiC), a sapphire (e.g., Al₂O₃), or any combination thereof. Substrate 109 may also include other semiconductor materials, metals, dielectrics, dopants, and other materials commonly found in semiconductor substrates.

Substrate 109 may include various dielectrics, which may be or include insulating materials with a same or different composition. Dielectrics may be conventional or low-permittivity (“low-K”) dielectrics that isolate various conductive elements.

Isolations 171, 172 (or portions of isolations 171, 172) may be trench isolations 171, 172 separating or bordering similar devices 100 on both sides. Isolations 171, 172 may be between adjacent transistor structures 110, 115, 120, 125 in adjacent standard cells. For example, isolation 171 may be between transistor structures 110, 120 in the standard cell shown and adjacent transistor structures 115, 125 in an adjacent standard cell. Similarly, isolation 172 may be between transistor structures 115, 125 in the standard cell shown and adjacent transistor structures 110, 120 in an adjacent standard cell. Isolations 171, 172 may be any structure(s) or material(s) that sufficiently isolate (e.g., electrically) structures 110, 115, 120, 125 from adjacent structures, e.g., in other standard cells or devices 100. In some embodiments, isolations 171, 172 are shallow trench isolations. In some embodiments, trench isolations 171, 172 are discontinuities between (or at an end of) channel structures in adjacent transistor structures (e.g., between structures 110, 115, 120, 125 and transistor structures in adjacent cells). In some such embodiments, isolations 171, 172 are of electrically insulating material (e.g., a low-K dielectric material) filled into a cavity (such as a trench) formed (e.g., by etching) in substrate 109 along structures (e.g., fins) including channel structures.

FIG. 1C illustrates level 102 of device 100, including supply interconnect lines 131, 132, 141, 142; input line 150; and output interconnect lines 161, 162, over other elements of device 100 (e.g., at level 101) and unobscured by elements of device 100 at level 103. At least some elements obscured by elements at level 102 are illustrated with dashed lines, such as vias represented as dashed rectangles with dashed diagonals between opposite corners. In some alternative embodiments, a “height” (in the y direction) of a standard cell (such as device 100) may be limited by the number of “tracks” (e.g., lines at level 102 running in the x direction), and only one of supply lines 130, 140 has two parallel supply interconnect lines 131, 132, 141, 142 at level 102.

Line 150 and interconnect lines 131, 132, 141, 142, 161, 162 are all physically parallel, running in the x direction at level 102 and are connected by vias to structures running in the y direction at levels 101, 103. Line 150 and interconnect lines 131, 132, 141, 142, 161, 162 may be of any suitable material(s) and form(s). In many embodiments, line 150 and interconnect lines 131, 132, 141, 142, 161, 162 are metallization structures within and/or through one or more dielectric layers over level 101 and substrate 109. For example, line 150 and interconnect lines 131, 132, 141, 142, 161, 162 may be metal bars, rails, or trenches through, and separated by, inter-metal dielectric over substrate 109. Vias 133, 143, 153, 163 may be metallization structures, e.g., substantially vertical structures, within and/or through one or more dielectric layers at or over level 101 and substrate 109. In some embodiments, line 150 and interconnect lines 131, 132, 141, 142, 161, 162 are in a Metal 0 (M0) layer of a metallized interconnect structure.

Line 150 and interconnect lines 131, 132, 141, 142, 161, 162 and vias 133, 143, 153, 163 may be formed by any suitable means. In many embodiments, line 150 and interconnect lines 131, 132, 141, 142, 161, 162 and vias 133, 143, 153, 163 are formed by damascene (or dual-damascene) methods. For example, a dielectric material may be formed in one or more layers (e.g., over level 101 and substrate 109) and selectively removed (e.g., by lithography and etching), and conductive material (such as metal) may be formed in the cavities formed by the removal of dielectric material. Vertical cavities may be formed (e.g., etched) through the dielectric material, down to level 101, to form vias coupling elements at levels 101, 102. Lateral cavities (e.g., trenches) may be formed in the dielectric material, over level 101, to form parallel interconnect lines at level 102. One or more conductive materials (e.g., metals) may be deployed. For example, a thin layer of a liner or seed metal may be deposited on sidewalls and horizontal surfaces of the dielectric material, and a bulk metal may then be grown over and within the liner metal. Excess conductor material may be removed by a planarization operation before a next layer of dielectric material is formed (e.g., over level 102, up to level 103).

Input line 150 extends in the x direction at level 102, over and coupled to gate structures 113, 118, 123, 128 (at level 101) by vias 153. Input line 150 is configured to conduct an input signal (e.g., into device 100) to gate structures 113, 118, 123, 128. Input line 150 is between supply interconnect lines 132, 141, which may shield line 150 from other lines, e.g., output interconnect lines 161, 162.

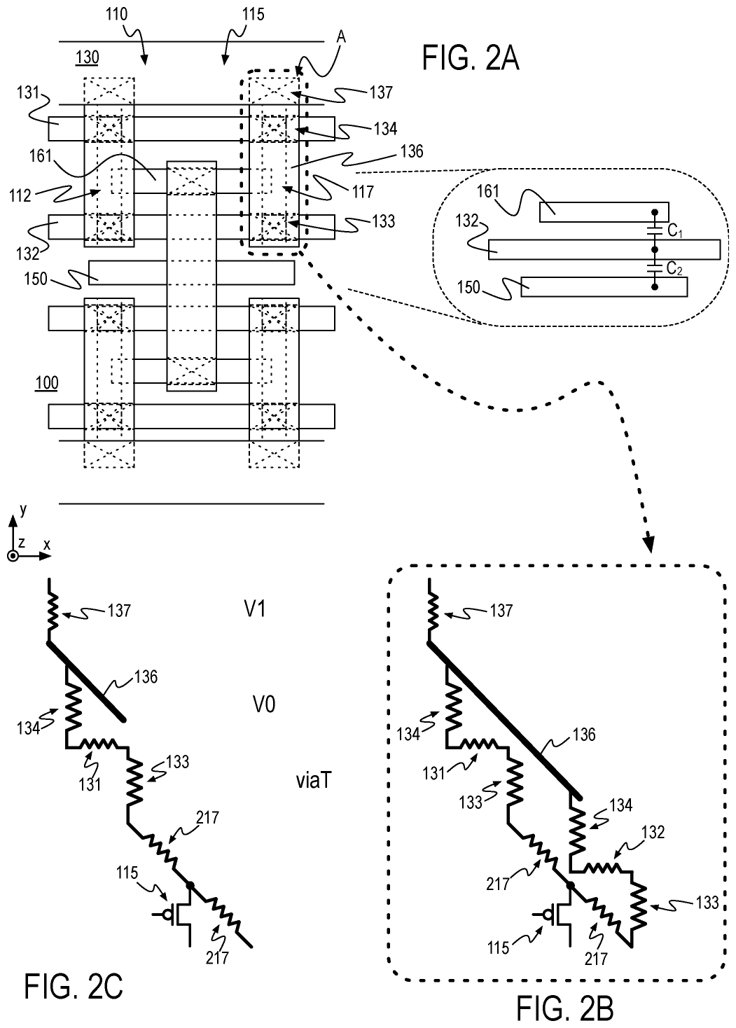

Interconnect lines 131, 132, 141, 142 are supply or power interconnect lines 131, 132, 141, 142 and couple power from power rail lines 130, 140 to source structures 112, 117, 122, 127 of transistor structures 110, 115, 120, 125. Parallel supply interconnect lines 131, 132 couple source structures 112, 117 (and so transistor structures 110, 115) at level 101 to supply line 130 at level 103. Parallel supply interconnect lines 141, 142 couple source structures 122, 127 (and so transistor structures 120, 125) at level 101 to supply line 140 at level 103. Interconnect lines 131, 132, 141, 142 extend in the x direction, which may enable coupling parallel structures (e.g., extending in the y direction) at level 101 (e.g., source structures 112, 117, 122, 127) and level 103 (e.g., supply interconnect lines 135, 136, 145, 146). Interconnect lines 131, 132 extending in the x direction also enables coupling source structures 112, 117, which (along with shared drain structure 111 and coupled gate structures 113, 118) provides the electrically parallel configurations of transistor structures 110, 115. Interconnect lines 141, 142 extending in the x direction enables coupling source structures 122, 127, providing the electrically parallel configurations of transistor structures 120, 125 (along with shared drain structure 121 and coupled gate structures 123, 128). In some embodiments, one or more of supply interconnect lines 131, 132, 141, 142 continue in the x directions beyond the edges of device 100 (or are portions of larger, continuous interconnects extending into adjacent devices, e.g., devices 100). Double-strapping power interconnect lines 131, 132, 141, 142 may have benefits as described elsewhere herein (e.g., FIGS. 2A-2C).

Output interconnect lines 161, 162 are output lines at level 102 (e.g., in M0) coupled to drain structures 111, 121 at level 101 by vias 163 and configured to conduct an output signal from drain structures 111, 121 (e.g., out of device 100 through output line 160 at level 103, shown in FIG. 1D). Output interconnect line 161 is between supply interconnect lines 131, 132, which may shield interconnect line 161 from other lines, e.g., input line 150. Output interconnect line 162 is between supply interconnect lines 141, 142, which may shield interconnect line 162 from other lines, e.g., input line 150. In some embodiments, output interconnect lines 161, 162 extending in the x direction each couple multiple, parallel drain structures (running in the y direction) at level 101 via vias 163. In some embodiments, output interconnect lines 161, 162 (each coupled to a single drain structure at level 101) are substantially the same length in the x and y directions (e.g., much like vias that do not extend in the x or y directions) coupling between vias 163, 164.

FIG. 1D shows level 103 of device 100, including output line 160 and supply interconnect lines 135, 136, 145, 146, as well as supply lines 130, 140 over level 103. Vias 134, 137, 144, 147, 164 (which couple elements at levels 102, 103) are obscured by various interconnect lines, but are shown dashed for reference. Input line 150 and supply interconnect lines 131, 132, 141, 142, 161, 162 at level 102 are also obscured by elements at level 103 and are shown dashed for reference.

Output line 160 and supply interconnect lines 135, 136, 145, 146 are all parallel conductive lines running in the y direction at level 103, which enables connections by vias to structures running in the x direction at level 102 and minimizes crosstalk between perpendicular lines at levels 102, 103. Line 160 and interconnect lines 135, 136, 145, 146 may be of any suitable material(s) and form(s). Line 160 and interconnect lines 135, 136, 145, 146 at level 103 may be much as line 150 and interconnect lines 131, 132, 141, 142, 161, 162 at level 102, e.g., metallization structures within and/or through one or more dielectric layers. For example, line 160 and interconnect lines 135, 136, 145, 146 may be metal bars, rails, or trenches through, and separated by, inter-metal dielectric over line 150 and interconnect lines 131, 132, 141, 142, 161, 162 at level 102. Vias 134, 137, 144, 147, 164 may similarly be metallization structures within and/or through one or more dielectric layers. In some embodiments, line 160 and interconnect lines 135, 136, 145, 146 are in a Metal 1 (M1) layer of a metallized interconnect structure and over layer M0. Line 160 and interconnect lines 135, 136, 145, 146 may be formed much as line 150 and interconnect lines 131, 132, 141, 142, 161, 162, for example, with a damascene process.

Output line 160 at level 103 (e.g., in layer M1) is coupled to output interconnect lines 161, 162 at level 102 (e.g., in M0) by vias 164. Output line 160 is coupled to drain structures 111, 121 by parallel output interconnect lines 161, 162 and by vias 163, 164. Output line 160 is configured to conduct an output signal from drain structures 111, 121 (e.g., out of device 100).

Supply lines 130, 140 may be power rails providing DC power to device 100. Supply lines 130, 140 are over level 103. Power rail supply lines 130, 140 may be similar to other lines or interconnect lines (e.g., metal bars, rails, or trenches), but in many embodiments, lines 130, 140 are larger than, e.g., line 160 and interconnect lines 135, 136, 145, 146 at level 103. Supply lines 130, 140 may continue in the x directions beyond the edges of device 100 and, for example, provide DC power to other devices 100. Supply interconnect lines 135, 136, 145, 146 are supply lines at level 103. Supply interconnect lines 135, 136 are coupled by vias 137 to supply line 130 over level 103. Supply interconnect lines 145, 146 are coupled by vias 147 to supply line 140 over level 103.

FIGS. 2A, 2B, and 2C illustrate plan and schematic views of portions of inverter device 100, including supply interconnect lines 131, 132, 136 and vias 133, 134 over source structure 117 of transistor structure 115, in accordance with some embodiments. FIG. 2A shows a plan view of device 100, including dashed portion A with supply interconnect lines 131, 132, 136 and vias 133, 134 coupling source structure 117 to supply line 130. FIG. 2B illustrates a schematic representation of dashed portion A as a resistance network, including supply interconnect lines 131, 132, 136 and vias 133, 134 coupled to source structure 117. FIG. 2C illustrates a schematic representation of a resistance network lacking the double-strapped improvement of parallel supply interconnect line 132.

FIG. 2A shows device 100 in plan view and having an improved interconnect scheme with double-strapped power interconnect lines 131, 132 delivering power from supply line 130 to source structures 112, 117 of transistor structures 110, 115. Output interconnect line 161 is located between interconnect lines 131, 132. Conventional interconnects may have a single intermediate interconnect, often adjacent a power rail. Improved interconnection scheme deploys interconnect line 132 between output interconnect line 161 and input line 150. There (decoupled) interconnect line 132 provides parallel resistance paths for power delivery and may act as a shield, providing frequency improvement without sacrificing switching energy, instead of coupling output interconnect line 161 to input line 150. Note that without interconnect line 132 as a shield, input line 150 and output interconnect line 161 may couple directly with each other and may switch in opposite directions causing increased capacitance due to the Miller effect, as is described in further detail below. FIG. 2A also shows an additional, unobscured view of interconnect line 132, output interconnect line 161, and input line 150 with capacitances C₁, C₂ between interconnect line 132 and each of output interconnect line 161 and input line 150.

Although FIGS. 2A-2C describe the example of source structure 117, transistor structure 115, and supply interconnect lines 131, 132 coupled to supply line 130, source structures 112, 117 and transistor structures 110, 115 operate symmetrically with the same benefits. For example, like source structure 117, source structure 112 at level 101 has two contact vias 133 coupling structure 112 to two electrically and physically parallel interconnects at level 102 (e.g., lines 131, 132). Both of lines 131, 132 are coupled to supply line 130 by multiple connections (e.g., multiple vias 134; lines 135, 136; and multiple vias 137). Supply interconnect lines 141, 142 coupled to supply line 140 also provide the improvements to source structures 122, 127 of transistor structures 120, 125. Source structures 122, 127 at level 101 each have two contact vias 133 coupling structure 122 or 127 to two electrically and physically parallel interconnects at level 102 (e.g., lines 141, 142). Both of lines 141, 142 are coupled to supply line 140 by multiple connections (e.g., multiple vias 144; lines 145, 146; and multiple vias 147).

Conventional interconnection structures may include “dummy” lines within interconnect layers with floating metallization structures (e.g., at a same level and parallel with adjacent interconnects) not electrically connected to supplies or transistors. Dummy lines may be deployed, for example, to provide metallization density and ensure sufficient uniformity during fabrication, e.g., planarization. Such floating metallization, however, may couple output interconnect line 161 and input line 150 due to capacitances between metallizations, and the Miller effect increases the effective coupling capacitance due to the inverter gain. The larger, Miller coupling capacitance, C_{M}, is multiplicatively increased by the inverter gain such that C_{M}=C*(1+Aᵥ), where −Aᵥ is the voltage gain of the inverting amplifier and C is the feedback capacitance. For example, (if interconnect line 132 were instead a floating metallization) the feedback capacitance C would be a series combination of capacitances C₁, C₂ plus that series combination multiplied by a magnitude of the gain Aᵥ. If the inverter has an input voltage approximately equal to a voltage from one power supply and an output voltage approximately equal to a voltage from the other power supply, −Aᵥ is approximately −1, and C_{M} is about 2*C. With supply interconnect line 132 at signal ground (instead of floating), input line 150 is shielded from the output interconnect line 161, negating the Miller capacitance. The input capacitance is only that capacitance C₁ at input line 150, and output interconnect line 161 and input line 150 are not coupled by an effective capacitance increased by the inverter gain.

FIG. 2B illustrates a schematic representation of a resistance network having dual supply interconnect lines 131, 132, and FIG. 2C illustrates a schematic representation of a resistance network lacking the double-strapped improvement of parallel supply interconnect line 132 for comparison. The resistances of vias 137 and interconnect lines 136 are common to networks of FIGS. 2B and 2C and are in series with the parallel branches including vias 133, 134 and one of supply interconnect lines 131, 132. Each parallel branch also includes a resistance 217, which represents the resistance of the portion of source structure 117 between adjacent via 133 and a channel region of transistor structure 115. Multiple channel regions in transistor structures 115 with will have different paths to supply line 130 through via 137, e.g., with potentially unbalanced resistances 217 to each of vias 133. The combined resistance of the parallel branches is half of a single branch, and the resistance of the network of FIG. 2B is less than the resistance of the network of FIG. 2C. In many embodiments, the cross-sectional area of vias 137 and interconnect lines 136 are significantly larger than the cross-sectional areas of vias 133, 134 and interconnect lines 131, 132. In such embodiments, the total network resistance may be dominated by the resistance of the lower levels of the network, which may be greatly reduced by adding parallel branches. Added branches (e.g., because of additional interconnect lines 131 or 132) mitigate against high contact resistance of vias 133 to source structure 117, which may be included in resistance 217.

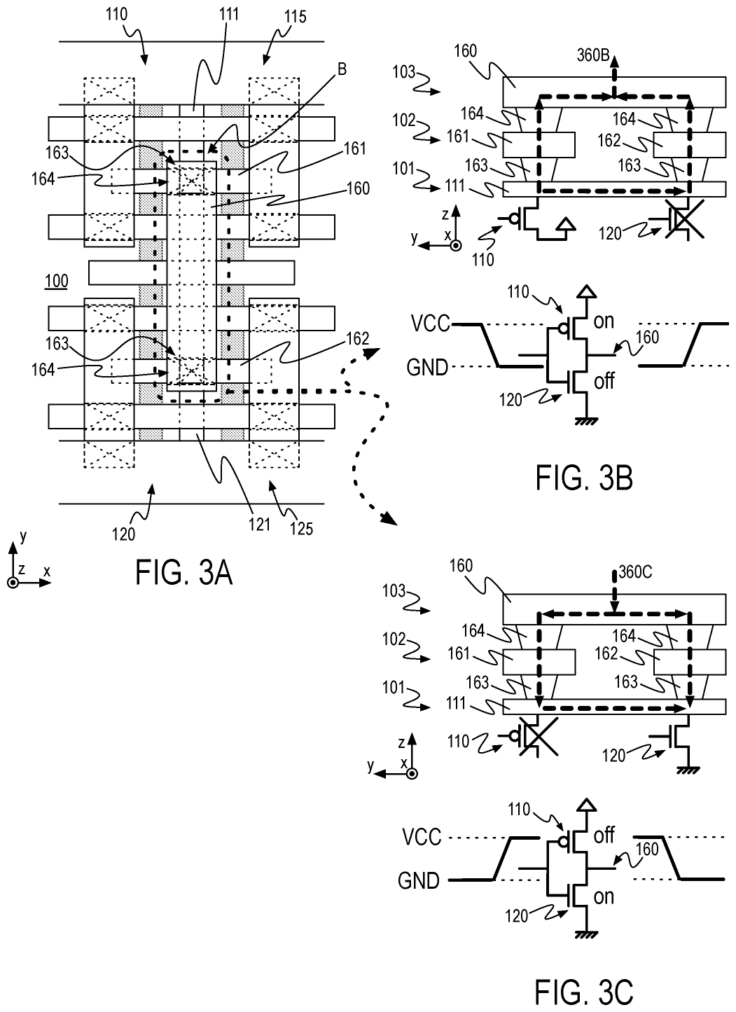

FIGS. 3A, 3B, and 3C illustrate plan, cross-sectional profile, and schematic views of portions of inverter device 100, including parallel output interconnect lines 161, 162 coupling output line 160 to drain structures 111, 121, in accordance with some embodiments. FIG. 3A shows device 100 in plan view, including dashed portion B, and having an improved interconnect scheme with parallel output interconnect lines 161, 162 coupling output line 160 to drain structures 111, 121 of transistor structures 110, 115, 120, 125.

Though sometimes referenced separately, drain structures 111, 121 may be a continuous structure with drain structure 111 being a portion over transistor structures 110, 115 and drain structure 121 being a portion over transistor structures 120, 125. In addition to any portion(s) below (e.g., coupling to channel regions), drain structures 111, 121 are coupled or continuous at level 101.

Parallel output interconnect lines 161, 162 (and vias 163, 164) couple drain structures 111, 121 to output line 160, which extend in the y direction to couple to both interconnect lines 161, 162.

FIGS. 3B and 3C illustrate cross-sectional profile and schematic views of portion B of device 100. FIG. 3B shows CMOS device 100 following an input transition from a logic level 1 (e.g., at a Vcc voltage) to a logic level 0 (e.g., at a ground voltage) and a corresponding output transition (e.g., at output line 160) from a logic level 0 (e.g., at a ground voltage) to a logic level 1 (e.g., at a Vcc voltage). Transistor structure 110 is on and driving output current 360B through output line 160, and transistor structure 120 is off. Drive current 360B has two parallel paths from transistor structure 110 out of output line 160. Drive current 360B flows from transistor structure 110 both through interconnect line 161 (via vias 163, 164 and to and through output line 160) and through drain structure 111 and interconnect line 162 (via vias 163, 164 and to and through output line 160).

FIG. 3C shows CMOS device 100 following an input transition from a logic level 0 (e.g., at a ground voltage) to a logic level 1 (e.g., at a Vcc voltage) and a corresponding output transition (e.g., at output line 160) from a logic level 1 (e.g., at a Vcc voltage) to a logic level 0 (e.g., at a ground voltage). Transistor structure 120 is on and driving output current 360C from output line 160, and transistor structure 110 is off. Drive current 360C has two parallel paths from and through output line 160 to transistor structure 120. Drive current 360C flows from output line 160 to transistor structure 120 both through interconnect line 162 (via vias 163, 164) and through interconnect line 161 and drain structure 111 (via vias 163, 164).

One of parallel output interconnect lines 161, 162 is over each of drain structures 111, 121, but generally one of the pull-up networks (e.g., transistor structures 110, 115) and the pull-down network (e.g., transistor structures 120, 125) is off, such that the one of drain structures 111, 121 over the off network may be used by the on network concurrently and in parallel with the other of drain structures 111, 121. The parallel paths (e.g., provided by, and requiring both of, multiple parallel output interconnect lines 161, 162 and by shunting the paths with multiple connections on both output line 160 and drain structures 111, 121) enable higher output drive currents 360B, 360C and reduced voltage drops across the output network. These benefits may also produce improved frequency response (e.g., higher cutoff frequency, or higher gain at high frequencies). While running a continuous drain structure 111, 121 alongside continuous gate structures 113, 123 and 118, 128 may increase coupling capacitances between drain and gate structures 111, 121 and 113, 123, 118, 128, such a coupling penalty is reduced at advanced technology nodes (e.g., in increasingly small standard cells) with diffusion wells packed more tightly together since a continuous drain structure 111, 121 need not be so long.

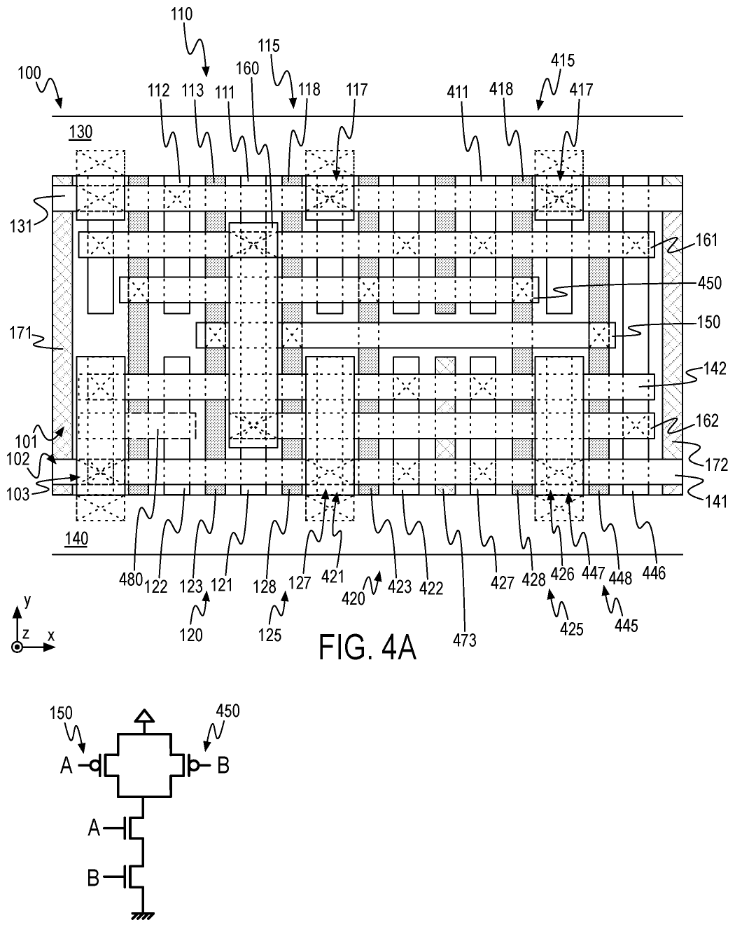

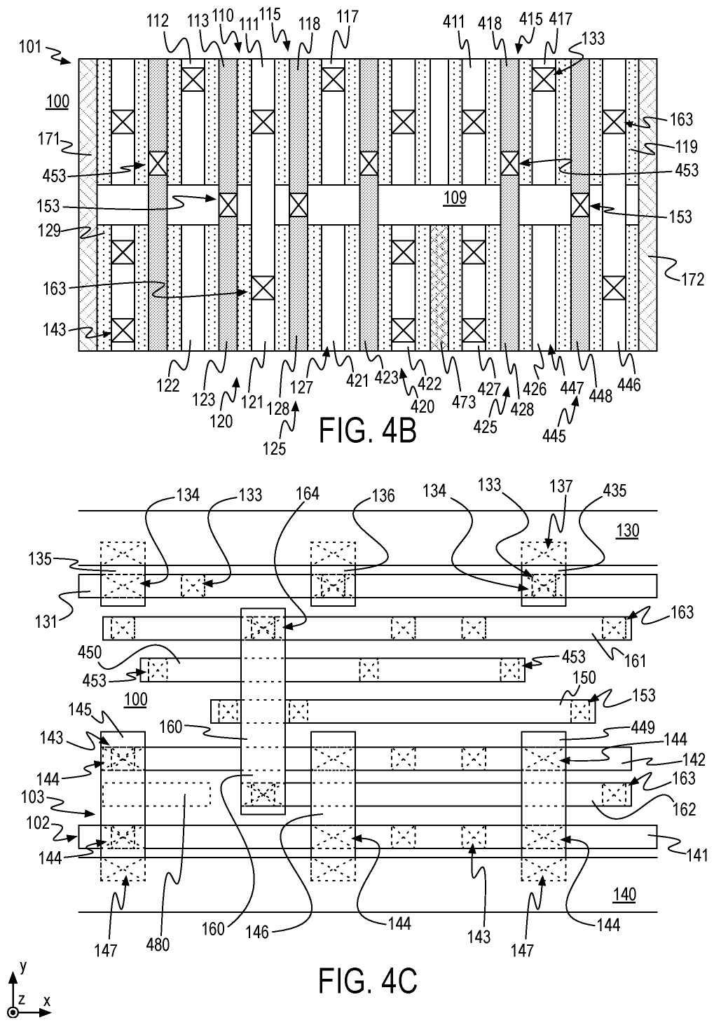

FIGS. 4A, 4B, and 4C illustrate plan views of a NAND device 100, including transistor structures 110, 115, 120, 125, 415, 420, 425, 445 between supply lines 130, 140 and isolation trench 473 between transistor structures 420, 425, in accordance with some embodiments. FIG. 4A shows elements of device 100 at, between, and over levels 101, 102, 103. The embodiment of device 100 at FIG. 4A-4C shares some similarities with other described embodiments. For example, device 100 is a CMOS device 100 with PMOS (p-type MOS) pull-up transistor structures 110, 115, 415 (and others) and NMOS (n-type MOS) pull-down transistor structures 120, 125, 420, 425, 445 (and others). Notably, device 100 presently described is a NAND gate (“Not AND”: logically, an inverted AND gate) and includes multiple input lines 150, 450. NAND device 100 is a “7 track” device with seven lines or interconnects running in the x direction at level 102. NAND device 100 includes multiple input lines 150, 450, but only a single supply interconnect line 131 at level 102 coupled to supply line 130. Multiple supply interconnect lines 141, 142 at level 102 are coupled to supply line 140.

Some gate structures (e.g., gate structures 113, 118, 123, 128, 448) are coupled to input line 150 (e.g., input A), and other gate structures (e.g., gate structures 418, 423, 428) are coupled to input line 450 (e.g., input B). Although gate structures 113, 118 (of transistor structures 110, 115) are coupled to input line 150 and gate structure 418 (of transistor structure 415) is coupled to input line 450, transistor structures 110, 115, 415 are all pull-up devices in a pull-up network. Source structures 112, 117, 417 (of transistor structures 110, 115, 415, respectively) are all coupled to supply line 130, and all of drain structures 111, 411 (of transistor structures 110, 115, 415) are coupled to output line 160. Transistor structures 110, 115, 415 are some of the transistor structures in pull-up network, which includes other transistor structures.

In the NAND gate of FIGS. 4A-4C, the pull-down network (e.g., having transistor structures 120, 420, 425, etc.) includes series-connected transistors between output line 160 and supply line 140. For example, transistor structures 420, 425 are coupled to output line 160 by transistor structures 125, 445. Transistor structures 125, 420 and 425, 445 are series-connected between output line 160 and supply line 140. (This configuration is in contrast to the examples of inverter devices 100 (e.g., at FIG. 1A), where all source structures were coupled to either of supply lines 130, 140 and all drain structures were coupled to output line 160.) Transistor structures 125, 445 respectively include drain structures 121, 446 coupled to output line 160, gate structures 128, 448 coupled to input line 150, and source structures 127, 447. Source structure 127 is shared with transistor structure 420, for which source structure 127 is drain structure 421. Source structure 447 is shared with transistor structure 425, for which source structure 447 is drain structure 426. Transistor structure 420 includes drain structure 421 (shared with or) coupled to transistor structure 125, gate structure 423 (over the channel region(s) of transistor structure 420 and) coupled to input line 450, and source structure 422 coupled to supply line 140. Transistor structure 425 includes drain structure 426 (series-coupled to output line 160 by adjacent transistor structure 445), gate structure 428 (over the channel region(s) of transistor structure 425 and) coupled to input line 450, and source structure 427 coupled to supply line 140. Both transistor structures 125, 420 (for example) conduct and together pull down output line 160 to the level (e.g., ground) of supply line 140 (and NAND device 100 produces a low logic level at output line 160) when logic-high signals (e.g., at a voltage level of Vcc) are present on both input lines 150, 450. The conduction of transistor structure 125 electrically couples output line 160 (on drain structure 121) to source structure 127, which is also drain structure 421 of transistor structure 420. The conduction of transistor structure 420 electrically couples drain structure 421 (which is also source structure 127 of transistor structure 125) to supply line 140 (e.g., ground, on source structure 422).

Isolation trench 473 separates transistor structures 420, 425. Transistor structures 420, 425 each include channel regions, and the channel region(s) of transistor structure 420 is separated from the channel region(s) of transistor structure 425 by isolation trench 473. Transistor structure 425 includes drain structure 426 (series-coupled to output line 160 by an adjacent transistor structure), gate structure 428 (over the channel region(s) of transistor structure 425 and) coupled to input line 450, and source structure 427 coupled to supply line 140. Isolation trench 473 separates source structures 422, 427, which are distinct, adjacent, and between corresponding drain structures 421, 426. Adjacent source structures 422, 427 are each the nearest source structure to the other. Adjacent source structures 422, 427 are both electrically connected to supply line 140. In conventional devices, distinct source structures 422, 427 would be integrated into a single conductive structure shared by adjacent transistor structures 420, 425, for example, to minimize a dimension (e.g., in the x direction) of device 100 and conserve cell area. Adjacent source structures 422, 427 are distinct structures 422, 427 (split out into separate, unshared source structures 422, 427), which provides separate, parallel current paths for drive current to and/or from supply line 140.

Isolation trench 473, or an equivalent structure, may be of any suitable material or form to separate transistor structures 420, 425. In some embodiments, previously continuous channel structures or regions of transistor structures 420, 425 are interrupted, e.g., separated or broken up, for example, by an etch through the channel region(s). In some such embodiments, a cavity, such as a trench across the channel region(s), is filled with a low-K dielectric or other insulator. In some embodiments, a dummy transistor is used between adjacent source structures 422, 427 and adjacent transistor structures 420, 425. For example, a transistor structure may be fabricated between adjacent source structures 422, 427 and adjacent transistor structures 420, 425, but not biased (e.g., coupled to either of supply lines 130, 140).

FIG. 4B illustrates elements of NAND device 100 at level 101, including isolation trench 473 in substrate 109 between transistor structures 420, 425. Vias 133, 143, 153, 163, 453 that couple between elements at levels 101, 102 are also shown (as rectangles with diagonals).

Transistor structures 110, 115, 120, 125, 415, 420, 425, 445 include drain structures 111, 121, 411, 421, 426, 446; source structures 112, 117, 122, 127, 417, 422, 427, 447; gate structures 113, 118, 123, 128, 418, 423, 428, 448; and channel structures (including channel regions; not shown) under corresponding gate structures and that couple corresponding drain and source structures. These (and all shown) drain, source, and gate structures run in the y direction, and most drain, source, and gate structures are coupled by vias to interconnects and other lines at level 102 over level 101. (Other transistor structures are shown but are not labelled with reference numbers.) Channel structures (including channel regions; not shown) run in the x direction under corresponding gate structures and couple corresponding drain and source structures.

For example, transistor structures 110, 115, 120, 125, 445 are coupled to input line 150 (e.g., input A) by input vias 153 on gate structures 113, 118, 123, 128, 448. Of those, pull-up transistor structures 110, 115 are coupled at source structures 112, 117 to supply line 130 by supply vias 133 and single supply interconnect line 131. Pull-up transistor structures 110, 115 are coupled at shared drain structure 111 to output line 160 by output vias 163. Pull-down transistor structures 120, 125, 445 (coupled to input line 150) are coupled at drain structures 121, 446 to output line 160 by output vias 163. Pull-down transistor structures 120, 125, 445 (coupled to input line 150) are coupled at source structures 122, 127, 447 to drain structures of pull-down transistors controlled by input line 450. Pull-down transistor structures 120, 125, 445 coupled to input line 150 are series-connected to pull-down transistor structures coupled to input line 450. Source structures 122, 127, 447 of pull-down transistor structures 120, 125, 445 coupled to input line 150 are coupled at (or integrated with) drain structures of pull-down transistors controlled by input line 450, for example, drain structures 421, 426 of pull-down transistor structures 420, 425.

Transistor structures 415, 420, 425 are coupled to input line 450 (e.g., input B) by input vias 453 on gate structures 418, 423, 428. Of those, pull-up transistor structure 415 is coupled at source structure 417 to supply line 130 by supply vias 133 and single supply interconnect line 131. Pull-down transistor structures 420, 425 coupled to input line 450 are series-connected to pull-down transistor structures coupled to input line 150. Drain structures 421, 426 of pull-down transistor structures 420, 425 coupled to input line 450 are coupled at (or integrated with) source structures of pull-down transistors controlled by input line 150, for example, source structures 127, 447 of pull-down transistor structures 125, 445. Pull-down transistor structures 420, 425 (coupled to input line 450) are coupled at source structures 422, 427 to supply line 140 by supply vias 143 and multiple supply interconnect lines 141, 142.

Isolation trench 473 is in substrate 109 between distinct, adjacent source structures 422, 427 of transistor structures 420, 425. Trench 473 and source structures 422, 427 extend in the y direction, and channel structures or regions of transistor structures 420, 425 extend in the x direction. Transistor structure 420 includes a channel structure under gate structure 423 and coupled to source structure 422. Transistor structure 425 includes a channel structure under gate structure 428 and coupled to source structure 427. Isolation trench 473 separates channel structures of transistor structures 420, 425 coupled to source structures 422, 427.

FIG. 4C shows elements of NAND device 100 at (and over) levels 102, 103, including various interconnect lines. Lines 150, 450 and interconnect lines 131, 141, 142, 161, 162 are at level 102 and run in the x direction. Line 160 and interconnect lines 135, 136, 435, 145, 146, 449 are at level 103 and run in the y direction. Lines 130, 140 are over level 103 and run in the x direction. Vias between levels 102, 103 (such as vias 134 over interconnect line 131 at level 102) are shown, as are vias over level 103 (such as vias 137 over interconnect lines 135, 136, 435 at level 103). Although below level 102, vias between levels 101, 102 are also shown for reference (such as vias 133 under interconnect line 131). All vias shown are obscured by interconnects or other lines over the vias, and all vias are shown as dashed rectangles and diagonals.

The interconnects and other lines at levels 102, 103 of NAND device 100 are much as described elsewhere herein, including for inverter devices 100, with some key differences. Notably, there are two input lines 150, 450 at level 102. Each of input lines 150, 450 are coupled to some of gate structures 113, 118, 123, 128, 418, 423, 428, 448 and configured to conduct an input signal (e.g., into device 100). For example, input line 150 is coupled to gate structures 113, 118, 123, 128, 448 (and others) by vias 153. Input line 450 is coupled to gate structures 418, 423, 428 (and others) by vias 453. Vias 153, 453 couple, and extend vertically between, input lines 150, 450 at level 102 and gate structures 113, 118, 123, 128, 418, 423, 428, 448 (and others) at level 101.

Some transistor structures are coupled at source structures at level 101 by various interconnects to supply lines 130, 140 over level 103. Notably, each of supply lines 130, 140 is coupled to more than two interconnects at level 103. Supply line 130 is coupled to supply interconnect lines 135, 136, 435 at level 103 by supply vias 137 over level 103. Supply line 140 is coupled to supply interconnect lines 145, 146, 449 at level 103 by supply vias 147 over level 103. Notably, supply line 130 interconnect lines 135, 136, 435 at level 103 are coupled (by supply vias 134 between levels 102, 103) to single supply interconnect line 131 at level 102. Supply line 140 interconnect lines 145, 146, 449 at level 103 are coupled (by supply vias 144 between levels 102, 103) to multiple supply interconnect lines 141, 142 at level 102. Source structures 112, 117, 417 at level 101 are coupled to single supply interconnect line 131 (and supply line 130) by supply vias 133 between levels 101, 102. Source structures 422, 427 (and one unlabeled source structure) at level 101 are coupled to multiple supply interconnect lines 141, 142 (and supply line 140) by supply vias 143 between levels 101, 102. Source structures 422, 427 are distinct, adjacent source structures 422, 427 of transistor structures 420, 425 and provide separate current paths from current structures of transistor structures 420, 425 (e.g., at and under level 101, and separated by isolation trench 473) to separate supply vias 143.

Notably, with series-connected transistor structures in the pull-down network of NAND device 100, not all drain structures are coupled to output line 160. Drain structures 111, 411 (and others) at level 101 in pull-up transistors are coupled through output vias 163 to output interconnect line 161 at level 102, and through output vias 164 to output line 160 at level 103. Drain structures 421, 426 at level 101 in pull-down transistors are coupled through output vias 163 to output interconnect line 162 at level 102, and through output vias 164 to output line 160 at level 103. Output interconnect line 162 at level 102 is parallel with and between supply interconnect lines 141, 142 at level 102.

NAND device 100 includes floating metallization structure 480 at level 102, between supply interconnect lines 141, 142 and in line with output interconnect line 162. Floating metallization structure 480 may provide metallization density and ensure sufficient metallization uniformity during fabrication, e.g., planarization.

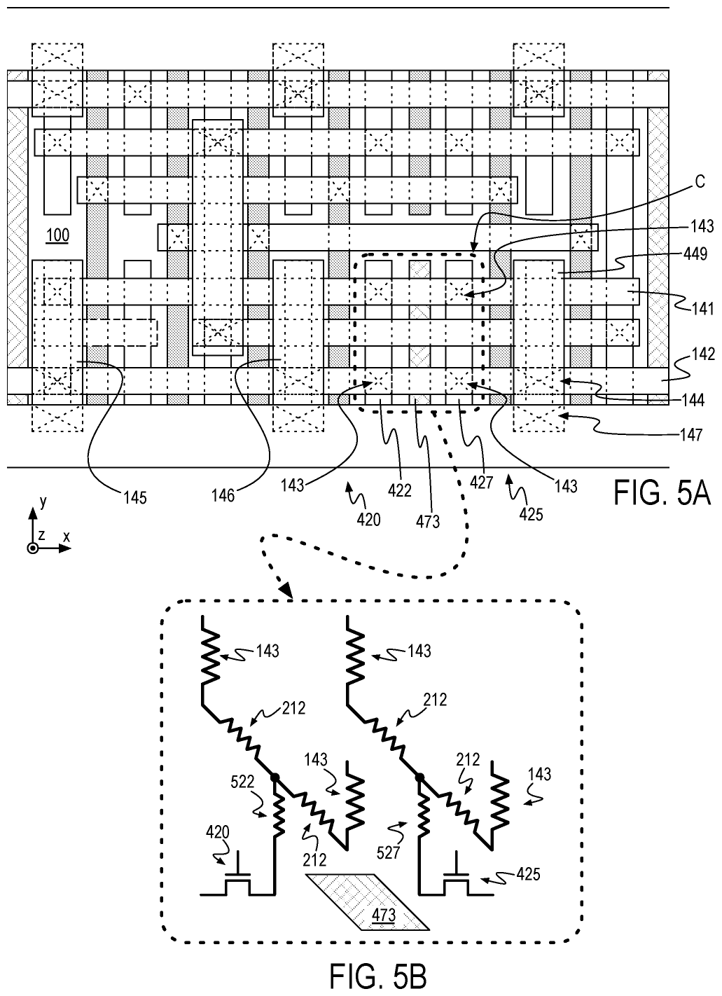

FIGS. 5A and 5B illustrate plan and schematic views of NAND device 100, including adjacent source structures 422, 427 separated by isolation trench 473, in accordance with some embodiments. FIG. 5A shows adjacent source structures 422, 427 (in dashed portion C) at level 101 are separate and not shared by adjacent transistor structures 420, 425. Each of source structures 422, 427 is coupled by two supply vias 143 to supply interconnect lines 141, 142 at level 102 and eventually up to supply line 140 (e.g., through supply interconnect lines 145, 146, 449 at level 103 and supply vias 144, 147). Unshared source structures 422, 427 and parallel interconnect networks improve the effective resistance of device 100 (e.g., the standard cell), as shown in FIG. 5B.

FIG. 5B illustrates a schematic representation of dashed portion C as a resistance network, including supply vias 143 coupled to source structures 422, 427 in a lower portion of parallel interconnect networks supplying power from supply line 140 to transistor structures 420, 425. The resistances of supply vias 143 are in parallel and connect to resistances 212, which represent the resistances of source structures 422, 427 at level 101, e.g., including source contact resistances. Resistances 522, 527 represent further resistances between associated channel regions of transistor structures 420, 425. Transistor structures 420, 425 are separated by isolation trench 473, and each of transistor structures 420, 425 has a parallel power delivery network. As described elsewhere (e.g., FIG. 2B), the effective resistance of a doubled-up, parallel network is half of a single, shared network. Although interconnects at upper levels 102, 103 are shared, upper interconnects (e.g., supply interconnect lines 141, 142 and especially supply interconnect lines 145, 146, 449 and supply line 140) may have much larger cross-sectional areas and much lower resistances. The effective resistance of the interconnect network may be dominated by the resistance of the lower levels of the network, and this effective resistance may be greatly reduced with added, parallel branches. Reduced effective resistance may improve device performance, and thereby the operable frequency range, by reducing RC delays and increasing drive currents.

Isolation trench 473 may be utilized between sources or drains (or both), in a pull-up or -down network (or both), etc. Because splitting a diffusion well (e.g., with an isolation between source and transistor structures) may introduce a junction capacitance, as well as growing the cell in the x direction, adding intracell isolation may be done sparingly and strategically. For example, the shared source of the pull-down network may be an optimal target for splitting for multiple reasons. First, transistor drive current is more sensitive to the source resistance than drain resistance due to the voltage drop across a source resistance reducing overdrive for the transistor (e.g., reducing gate bias over the threshold voltage). Secondly, for a NAND gate with equally sized n- and p-type FETs, average delay is more sensitive to the pull-down network, which must pull the output line down through two series-connected transistors (rather than parallel pull-up transistors). Additionally, a voltage drop across a source resistance (e.g., coupled to a grounded Vss) will typically vary less (and result in less RC delay) than over a drain resistance (e.g., varying between ground and Vcc).

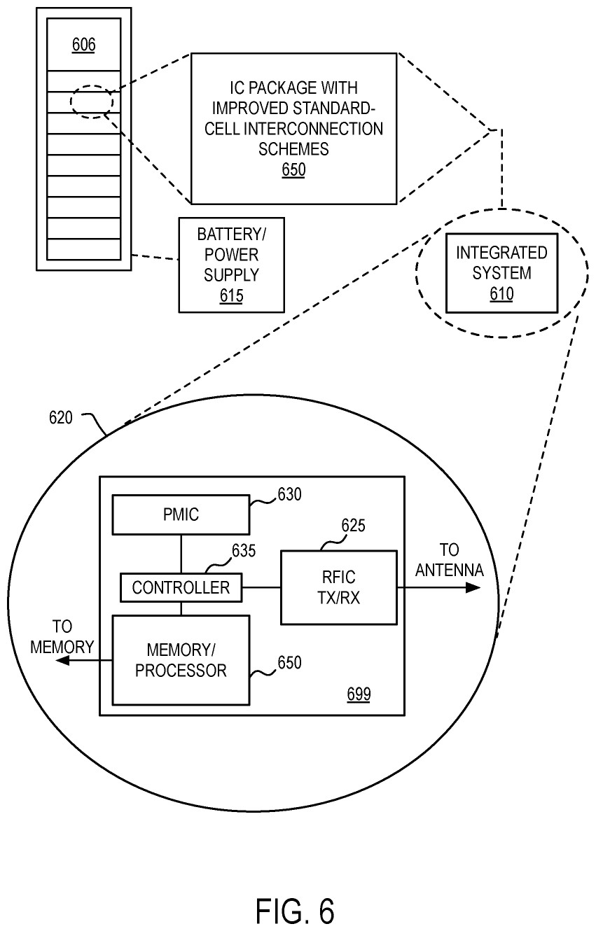

FIG. 6 illustrates a diagram of an example data server machine 606 employing an IC device having standard cells with improved interconnection schemes, in accordance with some embodiments. Server machine 606 may be any commercial server, for example, including any number of high-performance computing platforms disposed within a rack and networked together for electronic data processing, which in the exemplary embodiment includes one or more devices 650 with standard cells having improved interconnection schemes.

Also as shown, server machine 606 includes a battery and/or power supply 615 to provide power to devices 650, and to provide, in some embodiments, power delivery functions such as power regulation. Devices 650 may be deployed as part of a package-level integrated system 610. Integrated system 610 is further illustrated in the expanded view 620. In the exemplary embodiment, devices 650 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 650 is a microprocessor including a static RAM (SRAM) cache memory. As shown, device 650 may be an IC device having improved standard-cell interconnections, as discussed herein. Device 650 may be further coupled to (e.g., communicatively coupled to) a board, an interposer, or a substrate 699 along with, one or more of a power management IC (PMIC) 630, RF (wireless) IC (RFIC) 625 including a wideband RF (wireless) transmitter and/or receiver (TX/RX) (e.g., including a digital baseband and an analog front end module further includes a power amplifier on a transmit path and a low noise amplifier on a receive path), and a controller 635 thereof. In some embodiments, RFIC 625, PMIC 630, controller 635, and device 650 include standard cells with improved interconnection schemes.

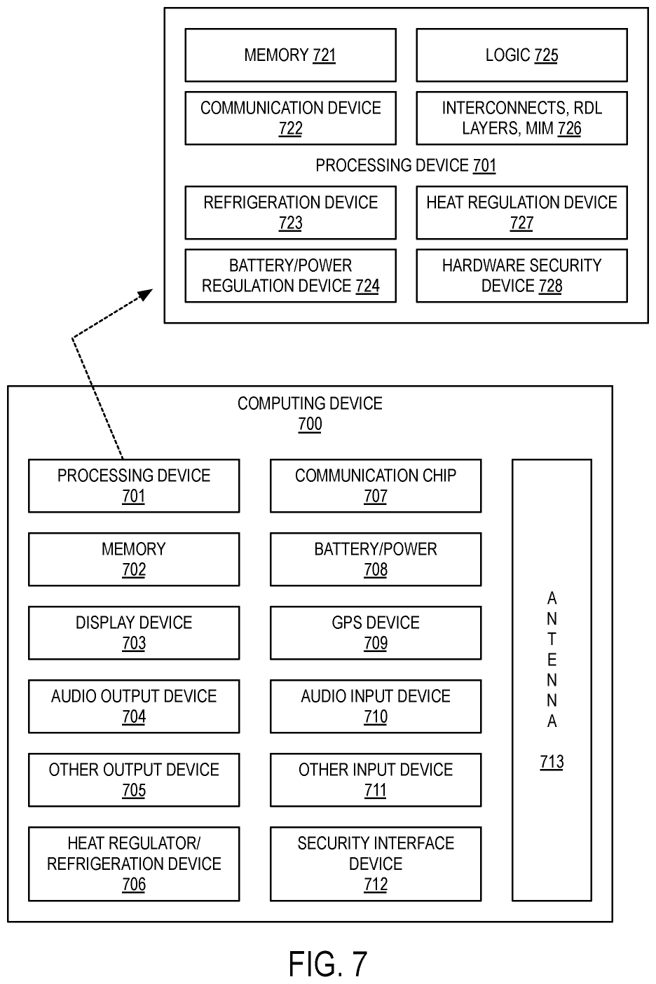

FIG. 7 is a block diagram of an example computing device 700, in accordance with some embodiments. For example, one or more components of computing device 700 may include any of the devices or structures discussed herein. A number of components are illustrated in FIG. 7 as being included in computing device 700, but any one or more of these components may be omitted or duplicated, as suitable for the application. In some embodiments, some or all of the components included in computing device 700 may be attached to one or more printed circuit boards (e.g., a motherboard). In some embodiments, various ones of these components may be fabricated onto a single system-on-a-chip (SoC) die. Additionally, in various embodiments, computing device 700 may not include one or more of the components illustrated in FIG. 7, but computing device 700 may include interface circuitry for coupling to the one or more components. For example, computing device 700 may not include a display device 703, but may include display device interface circuitry (e.g., a connector and driver circuitry) to which display device 703 may be coupled. In another set of examples, computing device 700 may not include an audio output device 704, other output device 705, global positioning system (GPS) device 709, audio input device 710, or other input device 711, but may include audio output device interface circuitry, other output device interface circuitry, GPS device interface circuitry, audio input device interface circuitry, audio input device interface circuitry, to which audio output device 704, other output device 705, GPS device 709, audio input device 710, or other input device 711 may be coupled.

Computing device 700 may include a processing device 701 (e.g., one or more processing devices). As used herein, the term “processing device” or “processor” indicates a device that processes electronic data from registers and/or memory to transform that electronic data into other electronic data that may be stored in registers and/or memory. Processing device 701 may include a memory 721, a communication device 722, a refrigeration device 723, a battery/power regulation device 724, logic 725, interconnects 726 (i.e., optionally including redistribution layers (RDL) or metal-insulator-metal (MIM) devices), a heat regulation device 727, and a hardware security device 728.

Processing device 701 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 700 may include a memory 702, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 702 includes memory that shares a die with processing device 701. This memory may be used as cache memory and may include embedded dynamic random-access memory (eDRAM) or spin transfer torque magnetic random-access memory (STT-MRAM).

Computing device 700 may include a heat regulation/refrigeration device 706. Heat regulation/refrigeration device 706 may maintain processing device 701 (and/or other components of computing device 700) at a predetermined low temperature during operation.

In some embodiments, computing device 700 may include a communication chip 707 (e.g., one or more communication chips). For example, the communication chip 707 may be configured for managing wireless communications for the transfer of data to and from computing device 700. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 707 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 707 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 707 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 707 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 707 may operate in accordance with other wireless protocols in other embodiments. Computing device 700 may include an antenna 713 to facilitate wireless communications and/or to receive other wireless communications (such as AM or FM radio transmissions).

In some embodiments, communication chip 707 may manage wired communications, such as electrical, optical, or any other suitable communication protocols (e.g., the Ethernet). As noted above, communication chip 707 may include multiple communication chips. For instance, a first communication chip 707 may be dedicated to shorter-range wireless communications such as Wi-Fi or Bluetooth, and a second communication chip 707 may be dedicated to longer-range wireless communications such as GPS, EDGE, GPRS, CDMA, WiMAX, LTE, EV-DO, or others. In some embodiments, a first communication chip 707 may be dedicated to wireless communications, and a second communication chip 707 may be dedicated to wired communications.

Computing device 700 may include battery/power circuitry 708. Battery/power circuitry 708 may include one or more energy storage devices (e.g., batteries or capacitors) and/or circuitry for coupling components of computing device 700 to an energy source separate from computing device 700 (e.g., AC line power).

Computing device 700 may include a display device 703 (or corresponding interface circuitry, as discussed above). Display device 703 may include any visual indicators, such as a heads-up display, a computer monitor, a projector, a touchscreen display, a liquid crystal display (LCD), a light-emitting diode display, or a flat panel display, for example.

Computing device 700 may include an audio output device 704 (or corresponding interface circuitry, as discussed above). Audio output device 704 may include any device that generates an audible indicator, such as speakers, headsets, or earbuds, for example.

Computing device 700 may include an audio input device 710 (or corresponding interface circuitry, as discussed above). Audio input device 710 may include any device that generates a signal representative of a sound, such as microphones, microphone arrays, or digital instruments (e.g., instruments having a musical instrument digital interface (MIDI) output).

Computing device 700 may include a GPS device 709 (or corresponding interface circuitry, as discussed above). GPS device 709 may be in communication with a satellite-based system and may receive a location of computing device 700, as known in the art.

Computing device 700 may include other output device 705 (or corresponding interface circuitry, as discussed above). Examples of the other output device 705 may include an audio codec, a video codec, a printer, a wired or wireless transmitter for providing information to other devices, or an additional storage device.

Computing device 700 may include other input device 711 (or corresponding interface circuitry, as discussed above). Examples of the other input device 711 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 700 may include a security interface device 712. Security interface device 712 may include any device that provides security measures for computing device 700 such as intrusion detection, biometric validation, security encode or decode, access list management, malware detection, or spyware detection.

Computing device 700, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-7. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes a first transistor structure, including a first gate structure, a first drain structure, and a first source structure, the first source structure coupled to a rail by a parallel pair of first interconnect lines at a same level and a pair of contact vias, a second transistor structure, including a second gate structure, a second drain structure, and a second source structure, wherein the first transistor structure is of a first conductivity type, and the second transistor structure is of a second conductivity type, complementary to the first conductivity type, a first line coupled to at least one of the first and second gate structures, and a second line coupled to the first and second drain structures.

In one or more second embodiments, further to the first embodiments, the first source structure extends in a first direction at a first level, the pair of first interconnect lines extends in a second direction perpendicular to the first direction at a second level over the first level, and the rail is at a third level over the second level.

In one or more third embodiments, further to the first or second embodiments, the second line is coupled to the first or second drain structure by a second interconnect line, the first line and the second interconnect line are at the second level, and a first of the first interconnect lines is between the first line and the interconnect line.

In one or more fourth embodiments, further to the first through third embodiments, the rail is a first rail, and further including a second rail, wherein the second source structure and the second rail are coupled by a parallel pair of second interconnect lines, wherein the second source structure extends in a first direction at a first level, and the pair of second interconnect lines extends in a second direction perpendicular to the first direction at a second level.

In one or more fifth embodiments, further to the first through fourth embodiments, the first line extends in the second direction at the second level, the second line extends in the first direction at a third level, the second line coupled to a parallel pair of third interconnect lines extending in the second direction at the second level, a first of the third interconnect lines is between the pair of first interconnect lines, the first line is between a second of the first interconnect lines and a first of the second interconnect lines, and a second of the third interconnect lines is between the pair of second interconnect lines.

In one or more sixth embodiments, further to the first through fifth embodiments, the first and second drain structures are coupled at a first level, and the first and second drain structures are coupled to the second line by a parallel pair of third interconnect lines at a second level.

In one or more seventh embodiments, further to the first through sixth embodiments, the apparatus also includes a third line, the first line is coupled to the first gate structure, and the third line is coupled to the second gate structure.

In one or more eighth embodiments, further to the first through seventh embodiments, the rail is a first rail, and further including a second rail and a third transistor structure, the third transistor structure of the second conductivity type, adjacent to the second transistor structure, and including a third source structure and a third drain structure, wherein the third source structure is coupled to the second rail, and the second and third source structures are distinct, adjacent, and between the second and third drain structures.

In one or more ninth embodiments, further to the first through eighth embodiments, the apparatus also includes third and fourth transistor structures, wherein the third transistor structure includes a third source structure and the first drain structure, the fourth transistor structure includes a fourth source structure and the second drain structure, the first drain structure is between and shared by the first and third transistor structures, and the second drain structure is between and shared by the second and fourth transistor structures.

In one or more tenth embodiments, an apparatus includes a first transistor structure, including a first source structure, a first gate structure, and a first drain structure, the first source structure coupled to a first rail, a second transistor structure, including a second source structure, a second gate structure, and a second drain structure, wherein the second source structure is coupled to a second rail, and the first and second drain structures are coupled at a first level, a first line coupled to at least one of the first and second gate structures, and a second line at a second level over the first level and coupled to the first drain structure by a first interconnect line over the first transistor structure and to the second drain structure by a second interconnect line over the second transistor structure.

In one or more eleventh embodiments, further to the tenth embodiments, the first source structure and the first rail are coupled by a parallel pair of third interconnect lines, the first source structure extends in a first direction at the first level, and the pair of third interconnect lines extends in a second direction perpendicular to the first direction at a third level between the first and second levels.

In one or more twelfth embodiments, further to the tenth or eleventh embodiments, the second source structure and the second rail are coupled by a parallel pair of fourth interconnect lines, the second source structure extends in the first direction at the first level, and the pair of fourth interconnect lines extends in the second direction at the third level.

In one or more thirteenth embodiments, further to the tenth through twelfth embodiments, the first interconnect line is between the pair of third interconnect lines at the third level, the second interconnect line is between the pair of fourth interconnect lines at the third level, and the first line extends in the second direction at the third level between one of the third interconnect lines and one of the fourth interconnect lines.

In one or more fourteenth embodiments, further to the tenth through thirteenth embodiments, the apparatus also includes a third line, the first line is coupled to the first gate structure, and the third line is coupled to the second gate structure.

In one or more fifteenth embodiments, further to the tenth through fourteenth embodiments, the apparatus also includes a third transistor structure adjacent to the second transistor structure, the third transistor structure comprises a third drain structure, a third source structure, and a third gate structure, wherein the third source structure is coupled to the second rail, and the second and third source structures are distinct, adjacent, and between the second and third drain structures.

In one or more sixteenth embodiments, an apparatus includes a first transistor structure, including a first drain structure coupled to a first line, a first source structure coupled to a first rail, and a first gate structure, a second transistor structure, including a second drain structure, a second source structure coupled to a second rail, and a second gate structure, a third transistor structure adjacent to the second transistor structure, the third transistor structure including a third drain structure, a third source structure coupled to the second rail, and a third gate structure, wherein the second and third source structures are distinct, adjacent, and between the second and third drain structures, and a second line coupled to at least one of the first, second, and third gate structures.

In one or more seventeenth embodiments, further to the sixteenth embodiments, the second and third source structures extend in a first direction, first and second channel structures extend in a second direction perpendicular to the first direction, the second channel structure coupled to the second source structure and the first channel structure coupled to the third source structure, and an isolation trench is between the first and second channel structures, and separates the second and third source structures.

In one or more eighteenth embodiments, further to the sixteenth or seventeenth embodiments, the second and third source structures extend in a first direction at a first level and are coupled to the second rail by parallel first and second interconnect lines extending in a second direction perpendicular to the first direction and at a second level, wherein the second source structure is coupled to the first interconnect line by a first via and to the second interconnect line by a second via, and the third source structure is coupled to the first interconnect line by a third via and to the second interconnect line by a fourth via.

In one or more nineteenth embodiments, further to the sixteenth through eighteenth embodiments, the second and third transistor structures are n-type transistors.

In one or more twentieth embodiments, further to the sixteenth through nineteenth embodiments, the second transistor structure is coupled to the first line by a fourth transistor structure, and the third transistor structure is coupled to the first line by a fifth transistor structure, wherein drain structures of the fourth and fifth transistor structures are coupled to the first line, the second and fourth transistor structures are coupled at the second drain structure, and the third and fifth transistor structures are coupled at the third drain structure.

In one or more twenty-first embodiments, further to the sixteenth through twentieth embodiments, the second and third source structures extend in a first direction at a first level and are coupled to the second rail by parallel first and second interconnect lines extending in a second direction perpendicular to the first direction and at a second level, and wherein the drain structures of the fourth and fifth transistor structures are coupled by an third interconnect line extending in the second direction and at the second level between the first and second interconnect lines.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
a first transistor structure, comprising a first gate structure, a first drain structure, and a first source structure, the first source structure coupled to a rail by a parallel pair of first interconnect lines at a same level and a pair of contact vias;
a second transistor structure, comprising a second gate structure, a second drain structure, and a second source structure, wherein the first transistor structure is of a first conductivity type, and the second transistor structure is of a second conductivity type, complementary to the first conductivity type;
a first line coupled to at least one of the first and second gate structures; and
a second line coupled to the first and second drain structures.

2. The apparatus of claim 1, wherein the first source structure extends in a first direction at a first level, the pair of first interconnect lines extends in a second direction perpendicular to the first direction at a second level over the first level, and the rail is at a third level over the second level.

3. The apparatus of claim 2, wherein the second line is coupled to the first or second drain structure by a second interconnect line, the first line and the second interconnect line are at the second level, and a first of the first interconnect lines is between the first line and the second interconnect line.

4. The apparatus of claim 1, wherein the rail is a first rail, and further comprising a second rail, wherein the second source structure and the second rail are coupled by a parallel pair of second interconnect lines, wherein the second source structure extends in a first direction at a first level, and the pair of second interconnect lines extends in a second direction perpendicular to the first direction at a second level.

5. The apparatus of claim 4, wherein:
the first line extends in the second direction at the second level;
the second line extends in the first direction at a third level, the second line coupled to a parallel pair of third interconnect lines extending in the second direction at the second level;
a first of the third interconnect lines is between the pair of first interconnect lines;
the first line is between a second of the first interconnect lines and a first of the second interconnect lines; and
a second of the third interconnect lines is between the pair of second interconnect lines.

6. The apparatus of claim 1, wherein the first and second drain structures are coupled at a first level, and the first and second drain structures are coupled to the second line by a parallel pair of third interconnect lines at a second level.

7. The apparatus of claim 1, further comprising a third line, wherein the first line is coupled to the first gate structure, and the third line is coupled to the second gate structure.

8. The apparatus of claim 1, wherein the rail is a first rail, and further comprising a second rail and a third transistor structure, the third transistor structure of the second conductivity type, adjacent to the second transistor structure, and comprising a third source structure and a third drain structure, wherein the third source structure is coupled to the second rail, and the second and third source structures are distinct, adjacent, and between the second and third drain structures.

9. An apparatus, comprising:
a first transistor structure, comprising a first source structure, a first gate structure, and a first drain structure, the first source structure coupled to a first rail;
a second transistor structure, comprising a second source structure, a second gate structure, and a second drain structure, wherein the second source structure is coupled to a second rail, and the first and second drain structures are coupled at a first level;
a first line coupled to at least one of the first and second gate structures; and
a second line at a second level over the first level and coupled to the first drain structure by a first interconnect line over the first transistor structure and to the second drain structure by a second interconnect line over the second transistor structure.

10. The apparatus of claim 9, wherein the first source structure and the first rail are coupled by a parallel pair of third interconnect lines, the first source structure extends in a first direction at the first level, and the pair of third interconnect lines extends in a second direction perpendicular to the first direction at a third level between the first and second levels.

11. The apparatus of claim 10, wherein the second source structure and the second rail are coupled by a parallel pair of fourth interconnect lines, the second source structure extends in the first direction at the first level, and the pair of fourth interconnect lines extends in the second direction at the third level.

12. The apparatus of claim 11, wherein:
the first interconnect line is between the pair of third interconnect lines at the third level;
the second interconnect line is between the pair of fourth interconnect lines at the third level; and
the first line extends in the second direction at the third level between one of the third interconnect lines and one of the fourth interconnect lines.

13. The apparatus of claim 9, further comprising a third line, wherein the first line is coupled to the first gate structure, and the third line is coupled to the second gate structure.

14. The apparatus of claim 9, further comprising a third transistor structure adjacent to the second transistor structure, the third transistor structure comprising a third drain structure, a third source structure, and a third gate structure, wherein the third source structure is coupled to the second rail, and the second and third source structures are distinct, adjacent, and between the second and third drain structures.

15. An apparatus, comprising:
a first transistor structure, comprising a first drain structure coupled to a first line, a first source structure coupled to a first rail, and a first gate structure;
a second transistor structure, comprising a second drain structure, a second source structure coupled to a second rail, and a second gate structure;
a third transistor structure adjacent to the second transistor structure, the third transistor structure comprising a third drain structure, a third source structure coupled to the second rail, and a third gate structure, wherein the second and third source structures are distinct, adjacent, and between the second and third drain structures; and
a second line coupled to at least one of the first, second, and third gate structures.

16. The apparatus of claim 15, wherein:
the second and third source structures extend in a first direction;
first and second channel structures extend in a second direction perpendicular to the first direction, the second channel structure coupled to the second source structure and the first channel structure coupled to the third source structure; and
an isolation trench is between the first and second channel structures, and separates the second and third source structures.

17. The apparatus of claim 15, wherein the second and third source structures extend in a first direction at a first level and are coupled to the second rail by parallel first and second interconnect lines extending in a second direction perpendicular to the first direction and at a second level, wherein the second source structure is coupled to the first interconnect line by a first via and to the second interconnect line by a second via, and the third source structure is coupled to the first interconnect line by a third via and to the second interconnect line by a fourth via.

18. The apparatus of claim 15, wherein the second and third transistor structures are n-type transistors.

19. The apparatus of claim 15, wherein the second transistor structure is coupled to the first line by a fourth transistor structure, and the third transistor structure is coupled to the first line by a fifth transistor structure, wherein drain structures of the fourth and fifth transistor structures are coupled to the first line, the second and fourth transistor structures are coupled at the second drain structure, and the third and fifth transistor structures are coupled at the third drain structure.

20. The apparatus of claim 19, wherein the second and third source structures extend in a first direction at a first level and are coupled to the second rail by parallel first and second interconnect lines extending in a second direction perpendicular to the first direction and at a second level, and wherein the drain structures of the fourth and fifth transistor structures are coupled by an third interconnect line extending in the second direction and at the second level between the first and second interconnect lines.
